(19) United States
(12) Patent Application Publication
(10) Pub. No.: US 2023/0178597 A1
(43) Pub. Date: Jun. 8, 2023

(54) SEMICONDUCTOR STRUCTURES WITH LOW TOP CONTACT RESISTANCE

(71) Applicant: International Business Machines Corporation, Armonk, NY (US)

(72) Inventors: Shogo Mochizuki, Mechanicville, NY (US); Kangguo Cheng, Schenectady, NY (US); Juntao Li, Cohoes, NY (US)

(21) Appl. No.: 17/541,879

(22) Filed: Dec. 3, 2021

(51) Int. Cl. H01L 29/06; H01L 29/423; H01L 29/786; H01L 21/8234

(52) U.S. Cl. CPC H01L 29/0665; H01L 29/42392; H01L 29/78618; H01L 29/78696; H01L 21/823418

(57) ABSTRACT

A semiconductor structure includes a source/drain region having a top surface comprising a planar portion and at least one recessed portion. A metal contact is disposed on the source/drain region.

### BACKGROUND

This disclosure relates generally to semiconductor fabrication techniques and, in particular, to structures and methods for fabricating semiconductor devices. The semiconductor integrated circuit (IC) industry has experienced rapid growth. In the course of the IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC manufacturing are needed.

### SUMMARY

Illustrative embodiments provide techniques for fabricating semiconductor devices.

According to an exemplary embodiment, a semiconductor structure comprises a source/drain region having a top surface comprising a planar portion and at least one recessed portion. The semiconductor structure further comprises a metal contact disposed on the source/drain region.

According to another exemplary embodiment, an integrated circuit comprises a plurality of semiconductor structures. At least one semiconductor structure of the plurality of semiconductor structures comprises a source/drain region having a top surface comprising a planar portion and at least one recessed portion. The at least one semiconductor structure further comprises a metal contact disposed on the source/drain region.

According to a further exemplary embodiment, a method for fabricating a semiconductor structure comprises forming a source/drain region having a top surface comprising a planar portion and at least one recessed portion. The method further comprises forming a metal contact on the source/drain region.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1A is a cross-sectional view illustrating a semiconductor structure at a first-intermediate fabrication stage, according to an illustrative embodiment.

FIG. 1B is a cross-sectional view of the semiconductor structure of FIG. 1A at the first-intermediate fabrication stage, according to an illustrative embodiment.

FIG. 2A is a cross-sectional view illustrating the semiconductor structure at a second-intermediate fabrication stage, according to an illustrative embodiment.

FIG. 2B is a cross-sectional view of the semiconductor structure taken along the cross-section axis of FIG. 1A at the second-intermediate fabrication stage, according to an illustrative embodiment.

FIG. 3A is a cross-sectional view illustrating the semiconductor structure at a third-intermediate fabrication stage, according to an illustrative embodiment.

FIG. 3B is a cross-sectional view of the semiconductor structure taken along the cross-section axis of FIG. 1A at the third-intermediate fabrication stage, according to an illustrative embodiment.

FIG. 4A is a cross-sectional view illustrating the semiconductor structure at a fourth-intermediate fabrication stage, according to an illustrative embodiment.

FIG. 4B is a cross-sectional view of the semiconductor structure taken along the cross-section axis of FIG. 1A at the fourth-intermediate fabrication stage, according to an illustrative embodiment.

FIG. 5A is a cross-sectional view illustrating the semiconductor structure at a fifth-intermediate fabrication stage, according to an illustrative embodiment.

FIG. 5B is a cross-sectional view of the semiconductor structure taken along the cross-section axis of FIG. 1A at the fifth-intermediate fabrication stage, according to an illustrative embodiment.

FIG. 6A is a cross-sectional view illustrating the semiconductor structure at a sixth-intermediate fabrication stage, according to an illustrative embodiment.

FIG. 6B is a cross-sectional view of the semiconductor structure taken along the cross-section axis of FIG. 1A at the sixth-intermediate fabrication stage, according to an illustrative embodiment.

FIG. 7A is a cross-sectional view illustrating the semiconductor structure at a seventh-intermediate fabrication stage, according to an illustrative embodiment.

FIG. 7B is a cross-sectional view of the semiconductor structure taken along the cross-section axis of FIG. 1A at the seventh-intermediate fabrication stage, according to an illustrative embodiment.

FIG. 8A is a cross-sectional view illustrating the semiconductor structure at an eighth-intermediate fabrication stage, according to an illustrative embodiment.

FIG. 8B is a cross-sectional view of the semiconductor structure taken along the cross-section axis of FIG. 1A at the eighth-intermediate fabrication stage, according to an illustrative embodiment.

FIG. 9A is a cross-sectional view illustrating the semiconductor structure at a ninth-intermediate fabrication stage, according to an illustrative embodiment.

FIG. 9B is a cross-sectional view of the semiconductor structure taken along the cross-section axis of FIG. 1A at the ninth-intermediate fabrication stage, according to an illustrative embodiment.

FIG. 10 is a cross-sectional view illustrating a semiconductor structure at a first-intermediate fabrication stage, according to an illustrative alternative embodiment.

FIG. 11 is a cross-sectional view illustrating the semiconductor structure at a second-intermediate fabrication stage, according to an illustrative alternative embodiment.

FIG. 12 is a cross-sectional view illustrating the semiconductor structure at a third-intermediate fabrication stage, according to an illustrative alternative embodiment.

FIG. 13A is a cross-sectional view illustrating the semiconductor structure at a fourth-intermediate fabrication stage, according to an illustrative alternative embodiment.

FIG. 13B is a cross-sectional view of the semiconductor structure taken along the cross-section axis of FIG. 13A at the fourth-intermediate fabrication stage, according to an illustrative alternative embodiment.

FIG. 13C is a cross-sectional view illustrating the semiconductor structure at the fourth-intermediate fabrication stage, according to another illustrative alternative embodiment.

FIG. 13D is a cross-sectional view of the semiconductor structure taken along the cross-section axis of FIG. 13C at the fourth-intermediate fabrication stage, according to an illustrative alternative embodiment.

FIG. 14A is a cross-sectional view illustrating the semiconductor structure at a fifth-intermediate fabrication stage, according to an illustrative alternative embodiment.

FIG. 14B is a cross-sectional view of the semiconductor structure taken along the cross-section axis of FIG. 13A at the fifth-intermediate fabrication stage, according to an illustrative alternative embodiment.

FIG. 15A is a cross-sectional view illustrating the semiconductor structure at a sixth-intermediate fabrication stage, according to an illustrative alternative embodiment.

FIG. 15B is a cross-sectional view of the semiconductor structure taken along the cross-section axis of FIG. 13A at the sixth-intermediate fabrication stage, according to an illustrative alternative embodiment.

FIG. 16A is a cross-sectional view illustrating the semiconductor structure at a seventh-intermediate fabrication stage, according to an illustrative alternative embodiment.

FIG. 16B is a cross-sectional view of the semiconductor structure taken along the cross-section axis of FIG. 13A at the seventh-intermediate fabrication stage, according to an illustrative alternative embodiment.

FIG. 17A is a cross-sectional view illustrating the semiconductor structure at an eighth-intermediate fabrication stage, according to an illustrative alternative embodiment.

FIG. 17B is a cross-sectional view of the semiconductor structure taken along the cross-section axis of FIG. 13A at the eighth-intermediate fabrication stage, according to an illustrative alternative embodiment.

FIG. 18A is a cross-sectional view illustrating the semiconductor structure at a ninth-intermediate fabrication stage, according to an illustrative alternative embodiment.

FIG. 18B is a cross-sectional view of the semiconductor structure taken along the cross-section axis of FIG. 13A at the ninth-intermediate fabrication stage, according to an illustrative alternative embodiment.

19A is a cross-sectional view illustrating the semiconductor structure at a tenth-intermediate fabrication stage, according to an illustrative alternative embodiment.

FIG. 19B is a cross-sectional view of the semiconductor structure taken along the cross-section axis of FIG. 13A at the tenth-intermediate fabrication stage, according to an illustrative alternative embodiment.

FIG. 20A is a cross-sectional view illustrating the semiconductor structure at an eleventh-intermediate fabrication stage, according to an illustrative alternative embodiment.

FIG. 20B is a cross-sectional view of the semiconductor structure taken along the cross-section axis of FIG. 13A at the eleventh-intermediate fabrication stage, according to an illustrative embodiment.

FIG. 20C is a cross-sectional view illustrating the semiconductor structure at the eleventh-intermediate fabrication stage based on the embodiment of FIG. 13C, according to another illustrative alternative embodiment.

FIG. 20D is a cross-sectional view of the semiconductor structure taken along the cross-section axis of FIG. 13C at the eleventh-intermediate fabrication stage, according to an illustrative alternative embodiment.

### DETAILED DESCRIPTION

This disclosure relates generally to transistors, and more particularly to semiconductor devices and methods for their fabrication.

For example, a field effect transistor (FET) is a semiconductor device that controls the electrical conductivity between a source of electric current (source) and a destination of the electrical current (drain). The FET uses a semiconductor structure called a gate to create an electric field, which controls the shape and consequently the electrical conductivity of a channel between the source and the drain. The channel is a charge carrier pathway constructed using a semiconductor material. A nanosheet FET transistor typically includes a substrate, an isolation layer, a number of vertically stacked nanosheets forming a channel, and a gate. A nanosheet is formed of a thin layer of semiconductor channel material having a vertical thickness that is less than a width of the material.

Another example is a fin-type field effect transistor (FinFET) device. Known FinFET devices include fins with source/drain regions on lateral sides of the fins, so that current flows in a horizontal direction (e.g., parallel to a substrate) between source/drain regions at opposite ends of the fins in the horizontal direction.

Another example includes vertical field effect transistors (VFETs) (also referred to as vertical transport field effect transistors (VTFETs)) which have also become viable device options for scaling semiconductor devices (e.g., CMOS devices) to 5 nanometer (nm) node and beyond. VFET devices include fin channels with source/drain regions at ends of the fin channels on top and bottom sides of the fins. Current flows through the fin channels in a vertical direction (e.g., perpendicular to a substrate), for example, from a bottom source/drain region to a top source/drain region.

Exemplary embodiments will now be discussed in further detail with regard to semiconductor devices and methods of manufacturing same and, in particular, to forming a top source/drain region in semiconductor devices that have a larger contact area thereby reducing the contact resistance.

Contact resistance is of a concern as transistor device scaling continues beyond the 5 nm technology node. The term contact resistance is the contribution to the total resistance of a material in which total resistance comes from the electrical leads and connections, as opposed to the intrinsic resistance that is an inherent property independent of the measurement method. Accordingly, illustrative non-limiting embodiments described herein correspond to semiconductor devices with a source/drain region having a top surface comprising a planar portion and at least one recessed portion. The at least one recessed portion of the source/drain region advantageously allow for a larger contact area thereby reducing contact resistance as compared to a source/drain region having only a planar top surface.

It is to be understood that the various layers and/or regions shown in the accompanying drawings are not drawn to scale, and that one or more layers and/or regions of a type commonly used in, for example, field-effect transistor (FET), FinFET, VFET, CMOS, nanowire FET, nanosheet FETs, metal-oxide-semiconductor field-effect transistor (MOSFET), single electron transistor (SET) and/or other semiconductor devices may not be explicitly shown in a given drawing. This does not imply that the layers and/or regions not explicitly shown are omitted from the actual devices. In addition, certain elements may be left out of particular views for the sake of clarity and/or simplicity when explanations are not necessarily focused on the omitted elements. Moreover, the same or similar reference numbers used throughout the drawings are used to denote the same or similar features, elements, or structures, and thus, a detailed explanation of the same or similar features, elements, or structures will not be repeated for each of the drawings. It is to be understood that the terms “about” or “substantially” as used herein with regard to thicknesses, widths, percentages, ranges, etc., are meant to denote being close or approximate to, but not exactly. For example, the terms “about” or “substantially” as used herein imply that a small margin of error may be present, such as 1% or less than the stated amount.

The semiconductor devices and methods for forming same in accordance with embodiments described herein can be employed in applications, hardware, and/or electronic systems. Suitable hardware and systems for implementing illustrative embodiments may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments. Given the teachings of illustrative embodiments provided herein, one of ordinary skill in the art will be able to contemplate other implementations and applications of embodiments described herein.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

As used herein, terms such as “upper”, “lower”, “right”, “left”, “vertical”, “horizontal”, “top”, “bottom”, and derivatives thereof shall relate to the disclosed structures and methods, as oriented in the figures. For example, as used herein, “vertical” refers to a direction perpendicular to the top surface of the substrate in the cross-sectional views, and “horizontal” refers to a direction parallel to the top surface of the substrate in the cross-sectional views.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

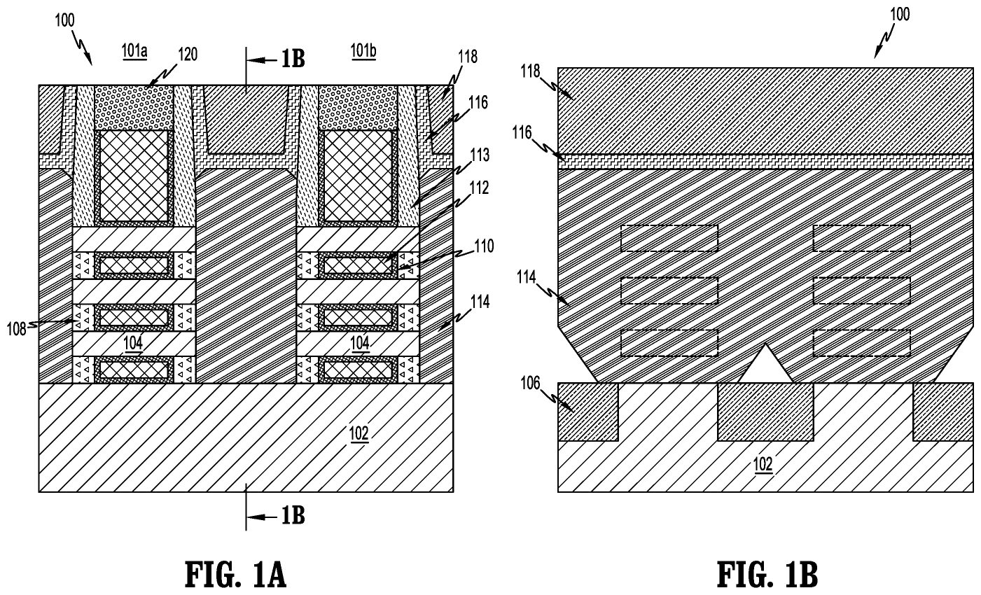

Referring now to the drawings in which like numerals represent the same of similar elements, FIGS. 1A-20D illustrate various processes for fabricating a semiconductor structure for increasing the top contact area on a source/drain region to reduce contact resistance. Note that the same reference numeral (100) is used to denote the semiconductor structure through the various intermediate fabrication stages illustrated in FIGS. 1A-9B. Note also that the semiconductor structure described herein can also be considered to be a semiconductor device and/or an integrated circuit, or some part thereof. For the purpose of clarity, some fabrication steps leading up to the production of the semiconductor structures as illustrated in FIGS. 1A-9B are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIGS. 1A and 1B illustrate semiconductor structure 100 at a first-intermediate fabrication stage. FIG. 1A shows a semiconductor structure 100 with a channel region 101a and a channel region 101b, e.g., a PFET region and an NFET region, disposed on substrate 102. Semiconductor structure 100 of FIGS. 1A and 1B include substrate 102. In general, substrate 102 can be composed of any currently known or later developed semiconductor material such as, for example, silicon (Si), germanium (Ge), silicon germanium (SiGe), silicon carbide (SiC), Si:C (carbon doped silicon), silicon germanium carbide (SiGeC), carbon doped silicon germanium (SiGe:C), compound semiconductor materials (e.g., Groups III-V), or other like semiconductor material. Semiconductor substrate 102 can also be a bulk substrate or a semiconductor-on-insulator substrate such as, but not limited to, a silicon-on-insulator (SOI), silicon-germanium-on-insulator (SGOI) or Groups III-V-on-insulator substrate including a buried insulating layer, such as, for example, a buried oxide, nitride layer or aluminum oxide.

A shallow trench isolation (STI) region 106 can be formed in substrate 102 (FIG. 1B). STI region 106 comprises a dielectric material such as silicon oxide or silicon oxynitride, and is formed by methods known in the art. In one illustrative embodiment, shallow trench isolation region 106 is a shallow trench isolation oxide layer.

Channel region 101a and channel region 101b each include nanosheet layers 104 and a gate structure disposed between each nanosheet layer 104 comprised of high-k dielectric layer 110 and work function metal 112 disposed between inner spacer 108. A gate structure comprising a high-k dielectric layer 110 and work function metal 112 is also disposed on a top surface of the uppermost nanosheet layer 104 with sidewall spacer 113 on the exterior surface thereof. Nanosheet layers 104 comprise a semiconducting material such as silicon. Inner spacers 108 can be composed of any suitable dielectric material, for example, silicon nitride, silicon oxide, silicon dioxide, silicon oxynitride, SiCN, SiOCN, SiOC, SiBCN, a dielectric metal oxide, a dielectric metal nitride, or a combination thereof. In one embodiment, the dielectric material is silicon nitride.

Suitable high-k dielectric material for high-k dielectric layer 110 includes, for example, hafnium oxide (HfO₂), HfSiO, HfSiON, AlO, Al₂O₃, titanium oxide (TiO₂), lanthanum oxide (La₂O₃) or a combination or stack thereof. The work function metal 112 includes one or more metals having a function suitable to tune the work function of channel regions 101a and 101b to a PFET region and/or an NFET region. For example, suitable work function metals include titanium nitride (TiN), titanium aluminum nitride (TiAlN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN); a carbide, including but not limited to titanium carbide (TiC) titanium aluminum carbide (TiAlC), tantalum carbide (TaC), hafnium carbide (HfC), and combinations thereof. In some embodiments, a conductive material or a combination of multiple conductive materials can serve as both gate conductor and work function metal.

The sidewall spacer 113 may be formed, for example, by forming a conformal layer of sidewall dielectric material and removing horizontal portions with a directional etch, e.g., reactive ion etching (RIE). In one illustrative embodiment, the sidewall spacer 113 can be a nitride or an oxynitride such as, for example, Si₃N₄, SiBCN, SiNC, SiN, SiCO, SiO₂ and SiNOC. In some exemplary embodiments, sidewall spacer 113 can include a material that is resistant to some etching processes such as, for example, HF chemical etching or chemical oxide removal etching.

Source/drain region 114 is epitaxially grown on substrate 102 between channel regions 101a and 101b. For example, source/drain region 114 is formed on substrate 102, around the sidewalls of nanosheet layers 104, inner spacers 108 and on a portion of sidewall spacer 113. The epitaxially grown source/drain region 114 can be in-situ doped, meaning dopants are incorporated into the epitaxy film during the epitaxy process. Other alternative doping techniques can be used, including but not limited to, for example, ion implantation, gas phase doping, plasma doping, plasma immersion ion implantation, cluster doping, infusion doping, liquid phase doping, solid phase doping, etc. Suitable dopants include, for example, an n-type dopant selected from a group of phosphorus (P), arsenic (As) and antimony (Sb), or a p-type dopant selected from a group of boron (B), gallium (Ga), indium (In), and thallium (Tl) at various concentrations. For example, in a non-limiting example, a dopant concentration range may be 1×10¹⁸/cm³ to 1×10²¹/cm³. It is to be understood that the term “source/drain region” as used herein means that a given source/drain region can be either a source region or a drain region, depending on the application.

Terms such as “epitaxial growth and/or deposition” and “epitaxially formed and/or grown” refer to the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on a semiconductor surface, and do not deposit material on dielectric surfaces, such as silicon dioxide or silicon nitride surfaces.

Examples of various epitaxial growth processes include, for example, rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for an epitaxial deposition process can range from 500° C. to 900° C. Although higher temperature typically results in faster deposition, the faster deposition may result in crystal defects and film cracking.

Etch-stop liner layer 116 is disposed on the top surface of source/drain region 114 and on a portion of sidewall spacer 113. A suitable material for etch-stop liner layer 116 includes, for example, silicon-nitride, although other material suitable in providing etch-stop function may be used as well.

An interlevel dielectric (ILD) layer 118 is disposed on a top surface of etch-stop liner layer 116. The ILD layer 118 includes, for example, any suitable dielectric material such as silicon oxide, silicon nitride, hydrogenated silicon carbon oxide, silicon based low-k dielectrics, flowable oxides, porous dielectrics, or organic dielectrics including porous organic dielectrics. Non-limiting examples of suitable low-k dielectric materials include a spin-on-glass, a flowable oxide, a high density plasma oxide, borophosphosilicate glass (BPSG), or any combination thereof. The ILD layer 118 may be formed using any suitable deposition techniques including chemical vapor deposition (CVD), physical vapor deposition (PVD), atomic layer deposition (ALD), plasma-enhanced CVD (PECVD), chemical solution deposition or other like processes. ILD layer 118 can be planarized by, for example, a planarization process such as chemical mechanical planarization (CMP), if needed.

A hardmask 120 is disposed over the top surface of high-k dielectric layer 110 and work function metal 112 and between sidewall spacer 113. Suitable material for hardmask 120 includes, for example, Si₃N₄, SiBCN, SiNC, SiN, SiCO, SiO₂, and SiNOC. Hardmask 120 can be deposited by conventional techniques, e.g., CVD.

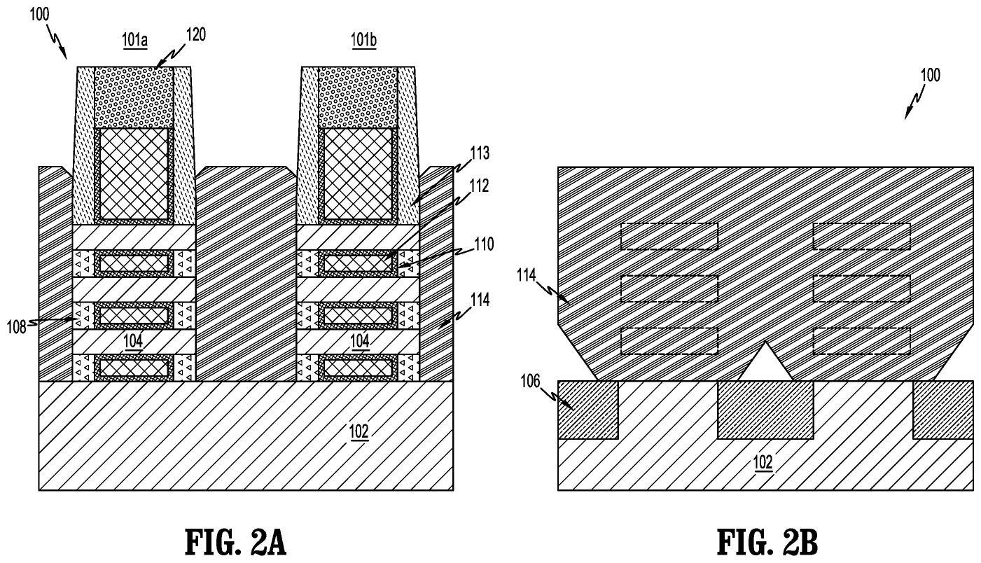

FIGS. 2A and 2B illustrate semiconductor structure 100 at a second-intermediate fabrication stage. During this stage, etch-stop liner layer 116 and ILD layer 118 are removed using conventional techniques such as RIE.

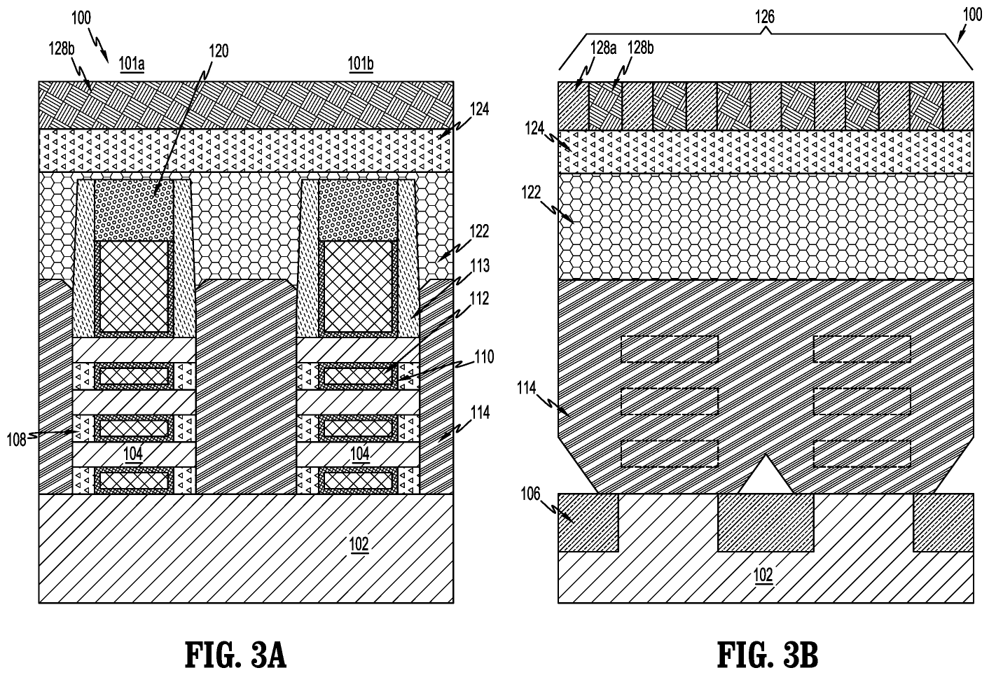

FIGS. 3A and 3B illustrate semiconductor structure 100 at a third-intermediate fabrication stage. During this stage, an organic planarization layer (OPL) 122 is selectively formed on source/drain region 114. The OPL 122 can be selectively deposited using, e.g., a spin-on coating process. The OPL 122 can be a self-planarizing organic material that includes carbon, hydrogen, oxygen, and optionally nitrogen, fluorine, and silicon. In one embodiment, the self-planarizing organic material can be a polymer with sufficiently low viscosity so that the top surface of the applied polymer forms a planar horizontal surface. In one embodiment, the OPL 122 can include a transparent organic polymer. The OPL can be a standard CxHy polymer. Suitable OPL materials include, for example, CHM701B, commercially available from Cheil Chemical Co., Ltd., HM8006 and HM8014, commercially available from JSR Corporation, and ODL-102 or ODL-401, commercially available from ShinEtsu Chemical, Co., Ltd.

Hardmask 124 is then deposited on the OPL 122 by conventional techniques, e.g., CVD. Suitable material for hardmask 124 includes, for example, Si₃N₄, SiBCN, SiNC, SiN, SiCO, SiO₂, and SiNOC. Hardmask 124 can then be planarized by, for example, CMP.

To facilitate high density patterning of source/drain regions 114, a directed self-assembly (DSA), i.e., pre-pattern aligned, of a di-block polymer 126 may be used to provide alternating blocks of two co-polymers 128 (i.e., 128a and 128b). Examples of the co-polymers 128 include block copolymers of poly(styrene (PS)-block-methyl methacrylate) or PS-b-PMMA.

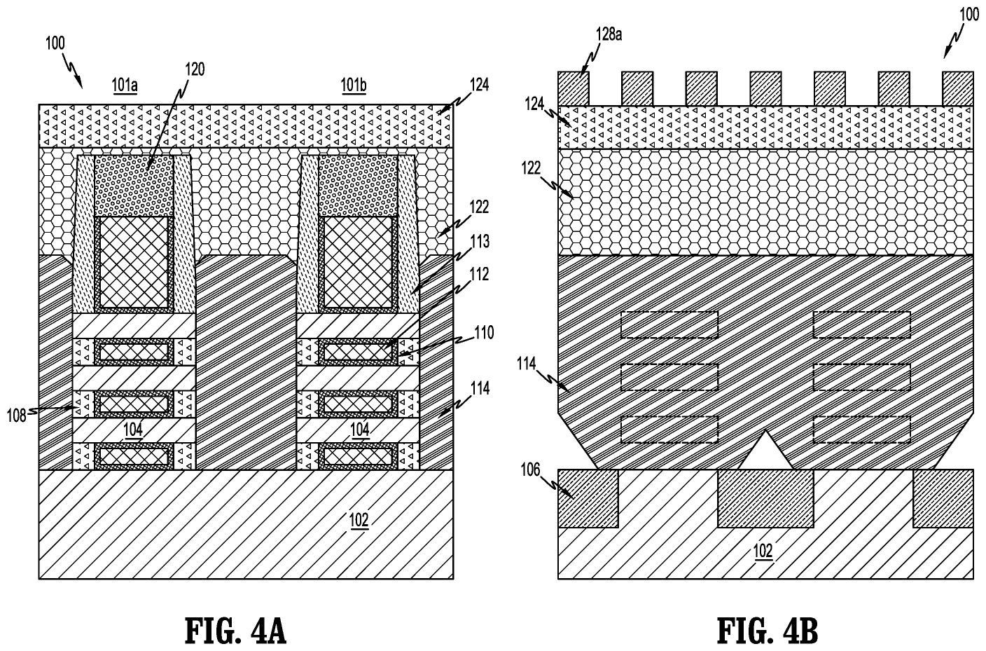

FIGS. 4A and 4B illustrate semiconductor structure 100 at a fourth-intermediate fabrication stage. During this stage, co-polymers 128 may undergo a first etch that selectively removes one of the co-polymers 128. In the depicted embodiment, the co-polymer 128b is removed and the co-polymer 128a is used as a mask for a second etch that patterns the semiconductor structure 100 as shown in FIG. 4B. The first etch can be any suitable wet etch, such as ammonia followed by a HF based solution, or a highly selective dry etch.

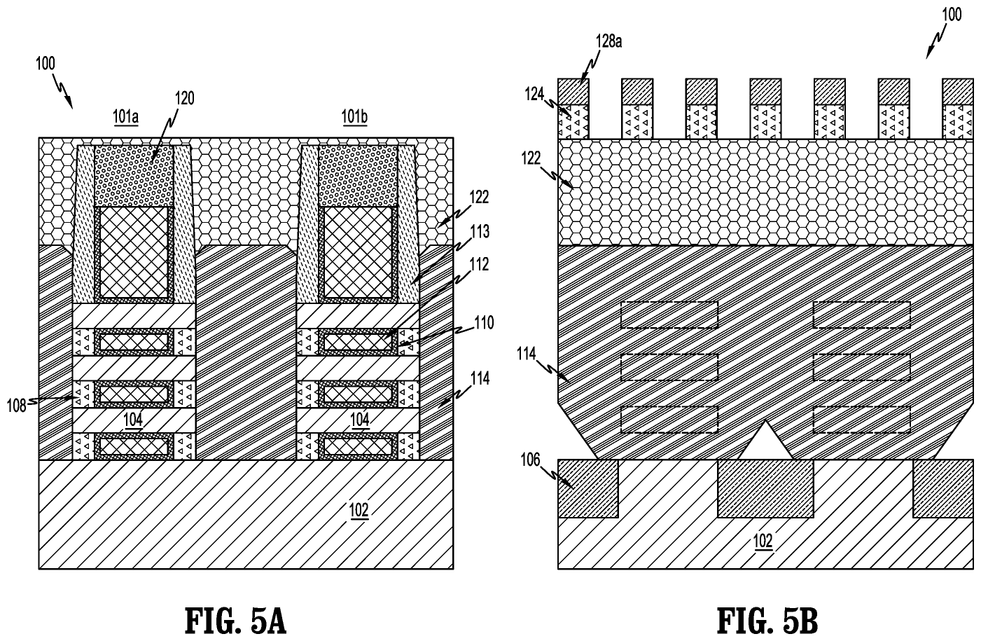

FIGS. 5A and 5B illustrate semiconductor structure 100 at a fifth-intermediate fabrication stage. During this stage, a second etch is performed using the co-polymer 128a as a mask to remove the exposed portion of hardmask 124 from the top surface of OPL 122 and leaving the unexposed portion of hardmask 124 under the co-polymer 128a. A suitable etch to remove the exposed portion of hardmask 124 includes a selective etch such as an RIE etch.

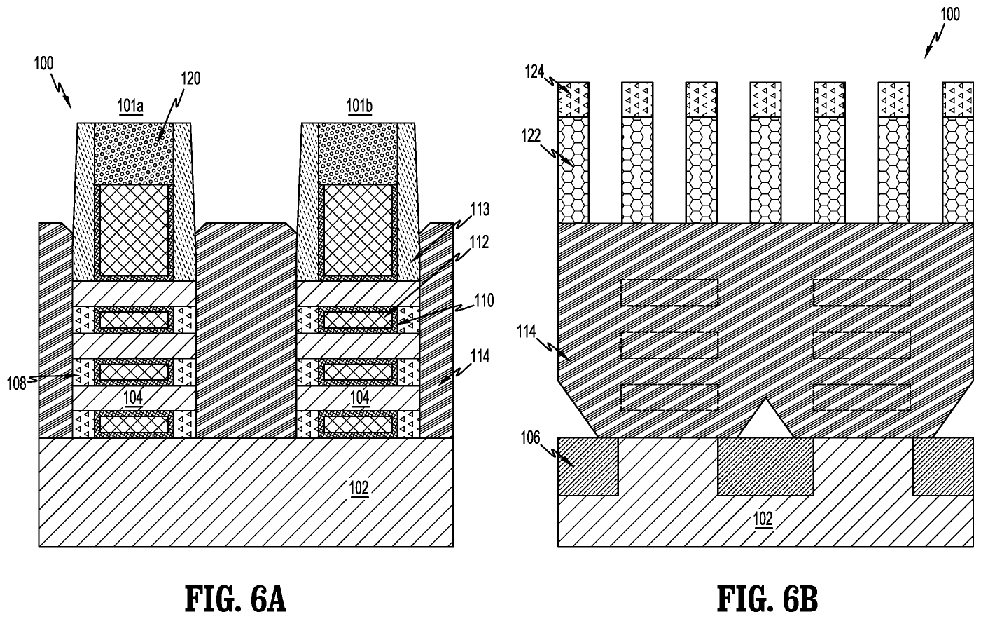

FIGS. 6A and 6B illustrate semiconductor structure 100 at a sixth-intermediate fabrication stage. During this stage, an etch is performed again using the co-polymer 128a as a mask to remove the exposed portion of OPL 122 leaving the unexposed portion of OPL 122 under hardmask 124 and the co-polymer 128a and exposing a top surface of source/drain region 114 between the resulting pillars of OPL 122, hardmask 124 and co-polymer 128a. A suitable etch to remove the exposed portion of OPL 122 includes a selective etch such as an RIE etch or a dry etch. The co-polymer 128a is selectively removed using any suitable wet etch, such as ammonia followed by a HF based solution, or a highly selective dry etch.

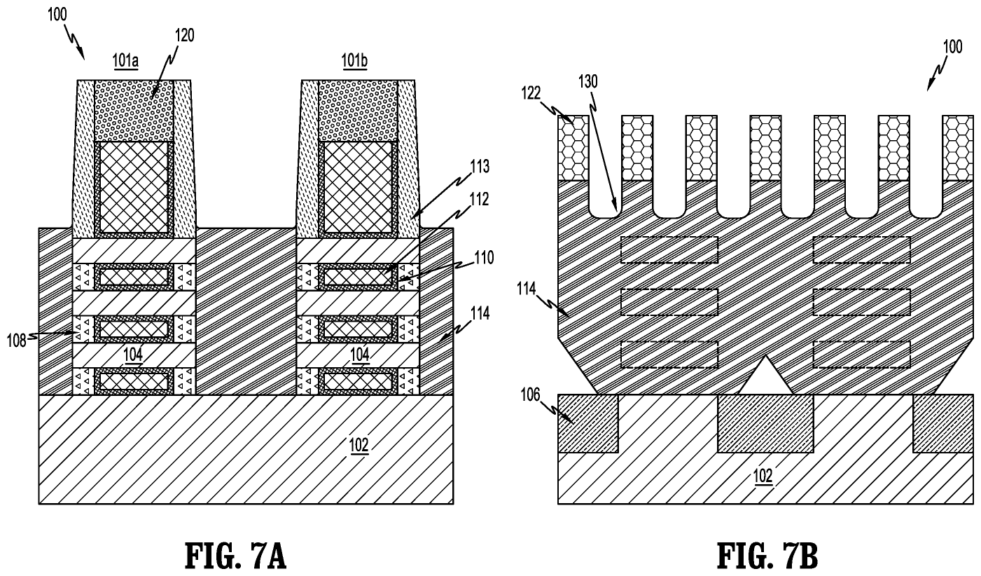

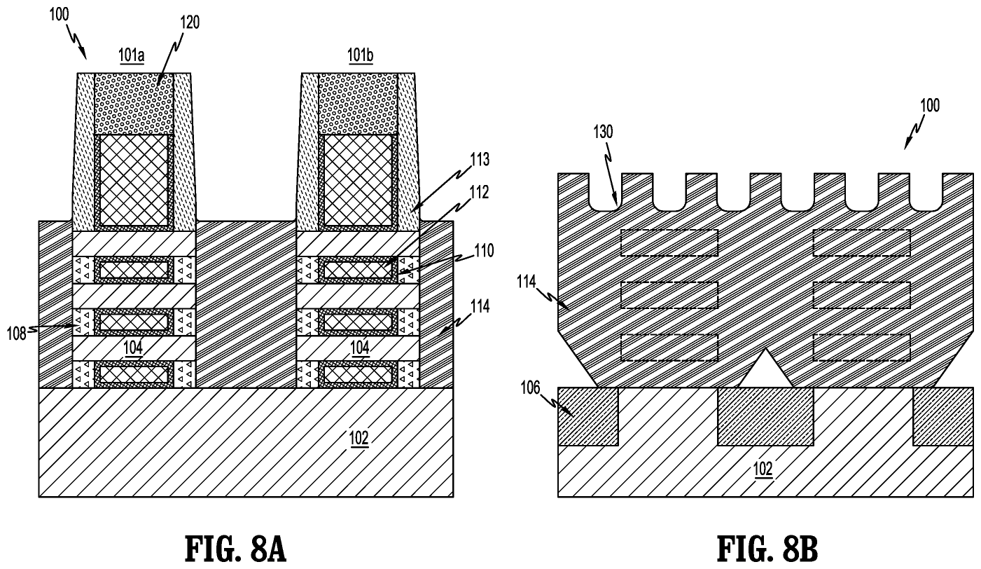

FIGS. 7A and 7B illustrate semiconductor structure 100 at a seventh-intermediate fabrication stage. During this stage, an etch is performed to recess the exposed surface of source/drain region 114 using any suitable dry etching technique. For example, the exposed surface of source/drain region 114 can be recessed by an isotropic etching process such as vapor phase dry etch. As shown in FIG. 7B, the exposed portion of source/drain region 114 between the resulting pillars of OPL 122 and hardmask 124 is etched so that the resulting top surface of source/drain region 114 will include a planar portion and at least one recessed portion 130 (see, also, FIG. 8B). Each of the recessed portions 130 can have a convex surface and a concave surface. The recessed portions 130 in the source/drain region 114 form a periodic convex and concave shaped structure.

FIGS. 8A and 8B illustrate semiconductor structure 100 at an eighth-intermediate fabrication stage. During this stage, OPL 122 is removed by any suitable process, e.g., using a standard O₂ or N₂/H₂ based OPL ash thereby resulting in the top surface of source/drain region 114 having the planar portion and the at least one recessed portion 130. Each of the recessed portions 130 can have a convex surface and a concave surface. The at least one recessed portion 130 of the source/drain region advantageously provides for a larger contact area of semiconductor structure 100 after depositing a metal contact as discussed below thereby reducing contact resistance as compared to a source/drain region having only a planar top surface.

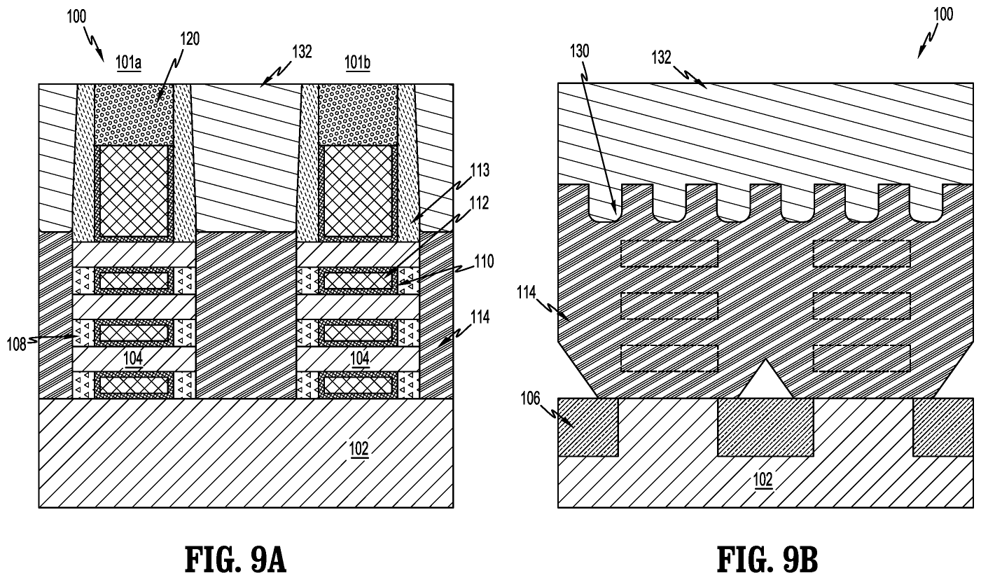

FIGS. 9A and 9B illustrate semiconductor structure 100 at a ninth-intermediate fabrication stage. During this stage, a metal contact 132 is deposited on the top surface of source/drain region 114 including in the at least one recessed portion 130 and over the planar portion. Suitable metals for metal contact 132 include any conductive material such as, for example, tungsten (W), aluminum (Al), copper (Cu), cobalt (Co), nickel (Ni), titanium (Ti), ruthenium (Ru), molybdenum (Mo), or any other suitable conductive material. In various embodiments, the metal contact 132 can be formed by ALD, CVD, PVD, and/or plating. The metal contact 132 can be planarized using, for example, a planarizing process such as CMP. Other planarization processes can include grinding and polishing.

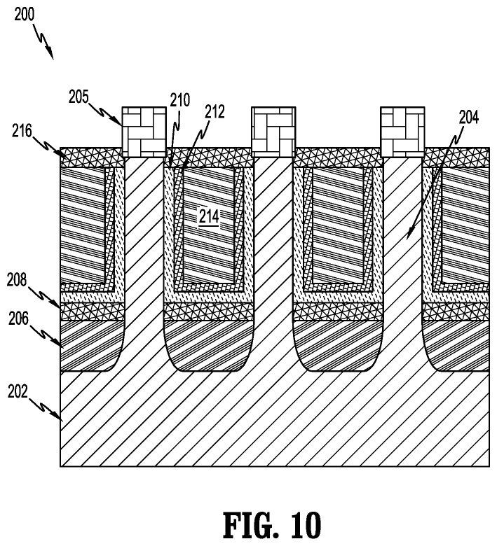

FIGS. 10-20D illustrate an alternate embodiment starting with the semiconductor structure 200. FIG. 10 is a cross-sectional view of the semiconductor structure 200 at a first-intermediate fabrication stage. Semiconductor structure 200 includes a semiconductor substrate 202 and a set of fins 204. Although three vertical fins for the set of fins 204 are shown, the number of fins should not be considered limiting. Thus, a “set of fins” as used herein can be considered as including one or more fins. The fins 204 may be formed using, for example, an anisotropic etch such as RIE that selectively removes material from the semiconductor substrate 202 in regions that are not protected by fin hardmasks 205. It should be understood that the fin hardmasks 205 may be formed from any appropriate masking material, but silicon nitride is specifically contemplated. As used herein, the term “selective” in reference to a material removal process denotes that the rate of material removal for a first material is greater than the rate of removal for at least another material of the structure to which the material removal process is being applied.

The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. In another embodiment, the semiconductor substrate 102 may also be a semiconductor on insulator (SOI) substrate.

Semiconductor structure 200 further includes bottom source/drain regions 206 formed in semiconductor substrate 202 between adjacent fins 204. One or more trenches are first formed in the semiconductor substrate 202 between fins 204, by for example, a wet or dry etch process. Bottom source/drain regions 206 are then formed in the trenches by, for example, epitaxial growth processes as discussed above. The epitaxially grown bottom source/drain regions 206 can be in-situ doped, meaning dopants are incorporated into the epitaxy film during the epitaxy process.

Semiconductor structure 200 further includes bottom spacer layer 208 formed on the bottom source/drain regions 206. Suitable material for bottom spacer layer 208 includes, for example, silicon boron nitride (SiBN), siliconborocarbonitride (SiBCN), silicon oxycarbonitride (SiOCN), SiN and SiOₓ. Bottom spacer layer 208 can be deposited using, for example, directional deposition techniques, such as a high-density plasma (HDP) deposition and gas cluster ion beam (GCIB) deposition. The directional deposition deposits the spacer material preferably on the exposed horizontal surfaces, but not on the lateral sidewalls. Alternatively, the spacer material can be deposited using, conformal deposition techniques, and removed from vertical surfaces using directional removal techniques, such as, for example, RIE. Any spacer material formed on the fins 204 can be removed using a planarization process, such as, for example, CMP.

Semiconductor structure 200 further includes a metal gate stack, i.e., gate structures, formed on bottom spacer layer 208 and on a portion of fins 204. In illustrative embodiments, gate dielectric layer 210 and a work function metal layer 212 are deposited to form the gate structures. Gate dielectric layer 210 is deposited on bottom spacer layer 208 and on a portion of fins 204 employing, for example, CVD, PECVD, RFCVD, PVD, ALD, or MLD. The gate dielectric layer 210 includes, for example, a high-K material such as HfO₂ (hafnium oxide), ZrO₂ (zirconium dioxide), hafnium zirconium oxide Al₂O₃ (aluminum oxide), and Ta₂O₅ (tantalum pentoxide). It will be appreciated that “high-k” generally refers to a dielectric material having a dielectric constant (k) value greater than that of silicon oxide. For example, the high-k material has a dielectric constant greater than about 5, or greater than about 10.

Work function metal layer 212 is deposited on gate dielectric layer 210. The work function metal layer 212 includes one or more metals having a function suitable to tune the work function of NFETs or PFETs. For example, suitable work function metals include titanium nitride (TiN), titanium aluminum nitride (TiAlN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN); a carbide, including but not limited to titanium carbide (TiC) titanium aluminum carbide (TiAlC), tantalum carbide (TaC), hafnium carbide (HfC), and combinations thereof. It is appreciated that an NFET uses one type of work function metal and a PFET uses another type of work function metal. In one example, the work function metal layer 212 can be TiN for a PFET, and the work function metal layer 212 can be Al-doped TiN or TaN, etc., for an NFET. In some embodiments, a conductive material or a combination of multiple conductive materials can serve as both gate conductor and work function metal. The work function metal layer 212 can be formed by any suitable process or any suitable combination of multiple processes, including but not limited to, ALD, CVD, PVD, sputtering, plating, evaporation, ion beam deposition, electron beam deposition, laser assisted deposition, chemical solution deposition, etc.

A metal fill 214 is deposited on work function metal layer 212 and fills the rest of the gate trench. Suitable metals for metal fill 214 include conductive material such as, for example, tungsten (W), aluminum (Al), copper (Cu), cobalt (Co), nickel (Ni), titanium (Ti), ruthenium (Ru), molybdenum (Mo), or any other suitable conductive material. In various embodiments, a barrier layer (not shown) can be deposited in the trench(es) by ALD, CVD, MOCVD, PECVD, or combinations thereof. In various embodiments, the metal fill 214 can be formed by ALD, CVD, PVD, and/or plating. The metal fill 214 can be planarized. The planarizing process can include CMP. Other planarization processes can include grinding and polishing.

Semiconductor structure 200 further includes a top spacer 216 formed on gate dielectric layer 210, work function metal layer 212 and metal fill 214 and on the remaining portion of the sidewalls of fins 204 and fin hardmask 205. The top spacer 216 includes, for example, silicon nitride (SiN), silicon boron nitride (SiBN), siliconborocarbonitride (SiBCN), or silicon oxycarbonitride (SiOCN). According to an embodiment, the top spacer 216 is conformally deposited using, for example, deposition techniques including, but not limited to, CVD, PECVD, PVD and ALD.

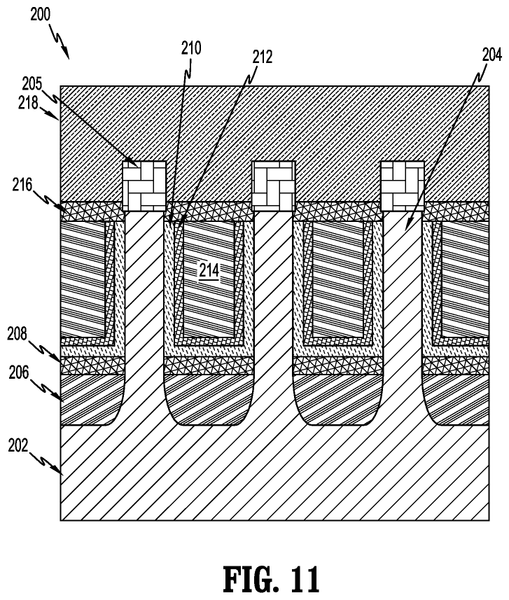

FIG. 11 illustrates semiconductor structure 200 at a second-intermediate fabrication stage. During this stage, an ILD layer 218 is deposited on semiconductor structure 200. The ILD layer 218 can be formed by a similar process and be of a similar material as ILD layer 118 discussed above.

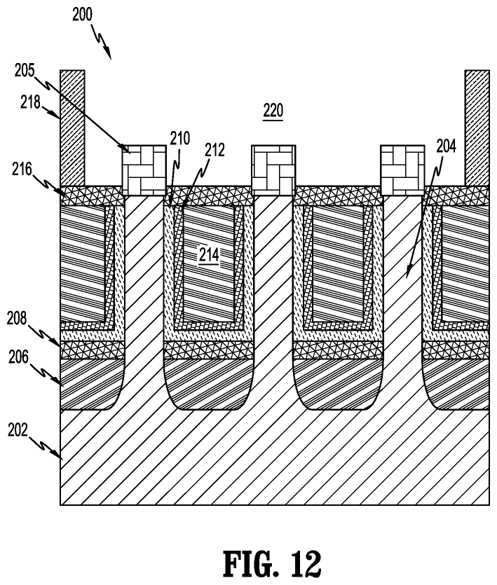

FIG. 12 illustrates semiconductor structure 200 at a third-intermediate fabrication stage. During this stage, ILD layer 218 is patterned using conventional techniques such as, for example, employing a hardmask on ILD layer 218 and etching to form a trench 220. Any suitable etching technique can be employed, e.g., ME.

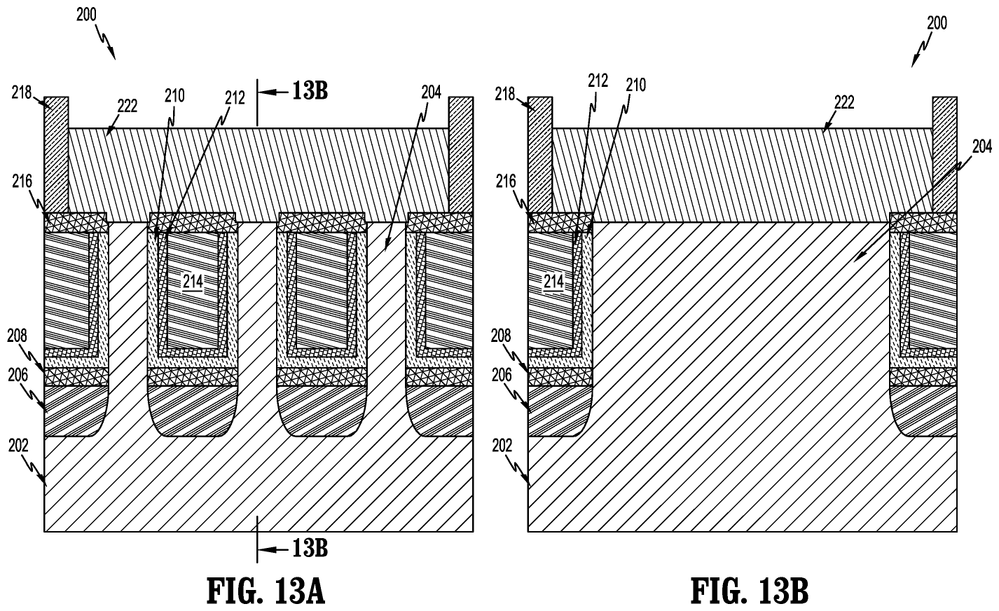

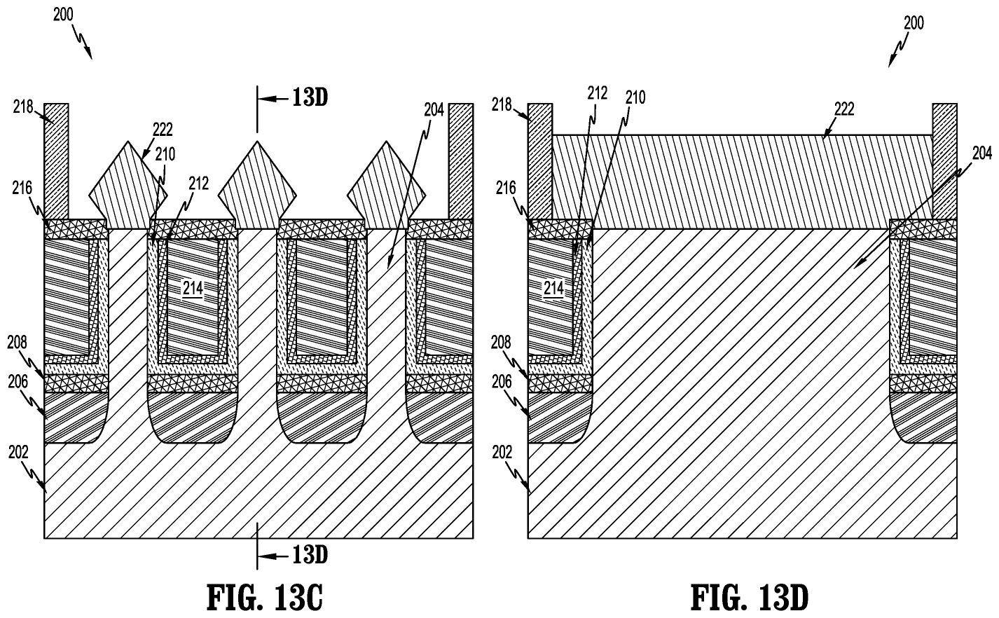

FIGS. 13A and 13B illustrate semiconductor structure 200 at a fourth-intermediate fabrication stage. During this stage, fin hardmask 205 is removed by, for example, ME, and source/drain region 222 is epitaxially grown in trench 220 and from the upper portions of the exposed fins 204 and top spacer 216 using epitaxial growth processes as described above to fill a portion of trench 220.

FIGS. 13C and 13D illustrate semiconductor structure 200 at a fourth-intermediate fabrication stage according to an alternative embodiment. In this embodiment, when forming source/drain region 222, a portion of the source/drain region is configured to have a lateral width less than a width, i.e., spacing, between adjacent gate structures on the respective fin. For example, in one embodiment, a portion of source/drain region 222 is formed in a diamond shaped configuration around the exposed upper portions of fins 204.

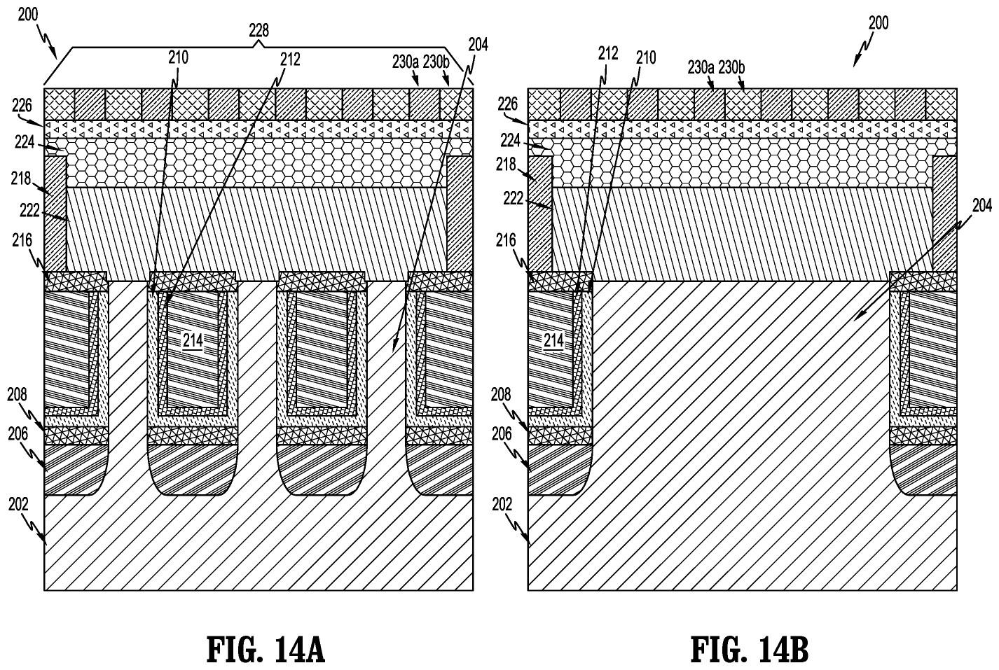

FIGS. 14A and 14B illustrate semiconductor structure 200 at a fifth-intermediate fabrication stage. During this stage, organic planarization layer (OPL) 224 is selectively deposited on source/drain region 222 and ILD layer 218. OPL 224 can be deposited in a similar manner and be of a similar material as OPL 122 discussed above. Hardmask 226 is then deposited on the OPL 224 in a similar manner and is of a similar material as hardmask 124 discussed above. Hardmask 226 can then be planarized by, for example, CMP.

To facilitate high density patterning of source/drain regions 222 and OPL 224, a directed self-assembly (DSA), i.e., pre-pattern aligned, of a di-block polymer 228 may be used to provide alternating blocks of two co-polymers 230 (i.e., 230a and 230b). Examples of the co-polymers 230 include block copolymers of poly(styrene (PS)-block-methyl methacrylate) or PS-b-PMMA.

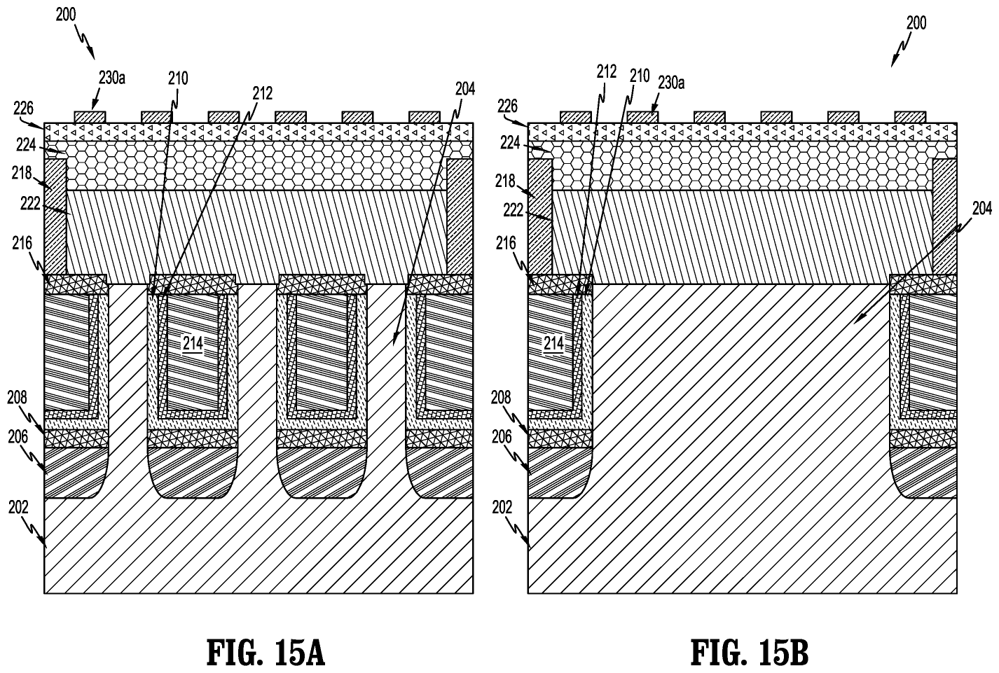

FIGS. 15A and 15B illustrate semiconductor structure 200 at a sixth-intermediate fabrication stage. During this stage, the co-polymers 230 may undergo a first etch that selectively removes one of the co-polymers 230. In the depicted embodiment, the co-polymer 230b is removed and the co-polymer 230a is used as a mask for a second etch that patterns the semiconductor structure 200 as shown in FIGS. 15A and 15B. The first etch can be any suitable wet etch, such as ammonia followed by a HF based solution, or a highly selective dry etch.

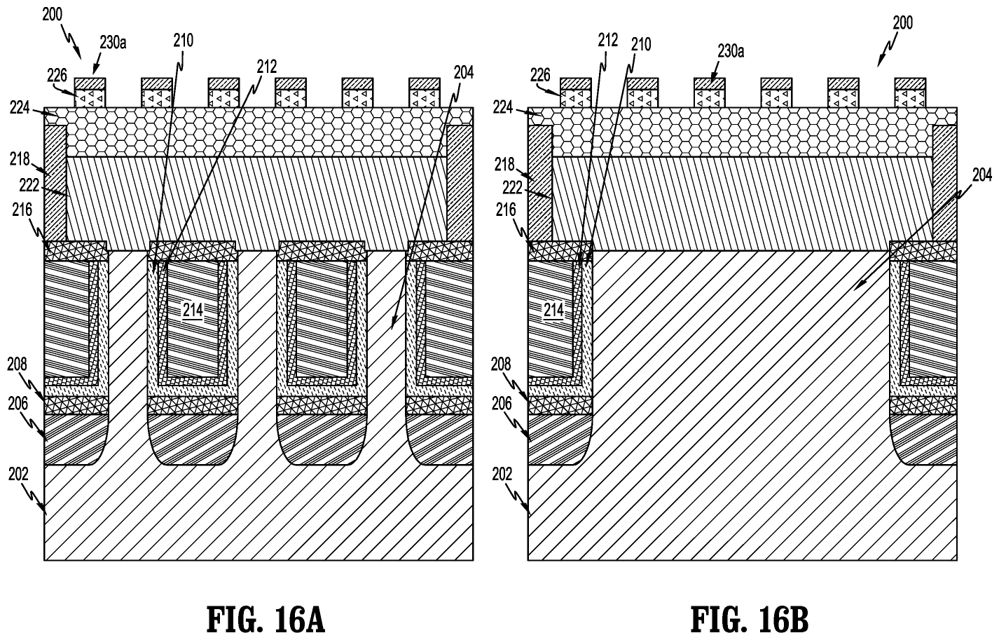

FIGS. 16A and 16B illustrate semiconductor structure 200 at a seventh-intermediate fabrication stage. During this stage, a second etch is performed using the co-polymer 230a as a mask to remove the exposed portion of hardmask 226 from the top surface of OPL 224 and leaving the unexposed portion of hardmask 226 under the co-polymer 230a. A suitable etch to remove the exposed portion of hardmask 226 includes a selective etch such as an RIE etch.

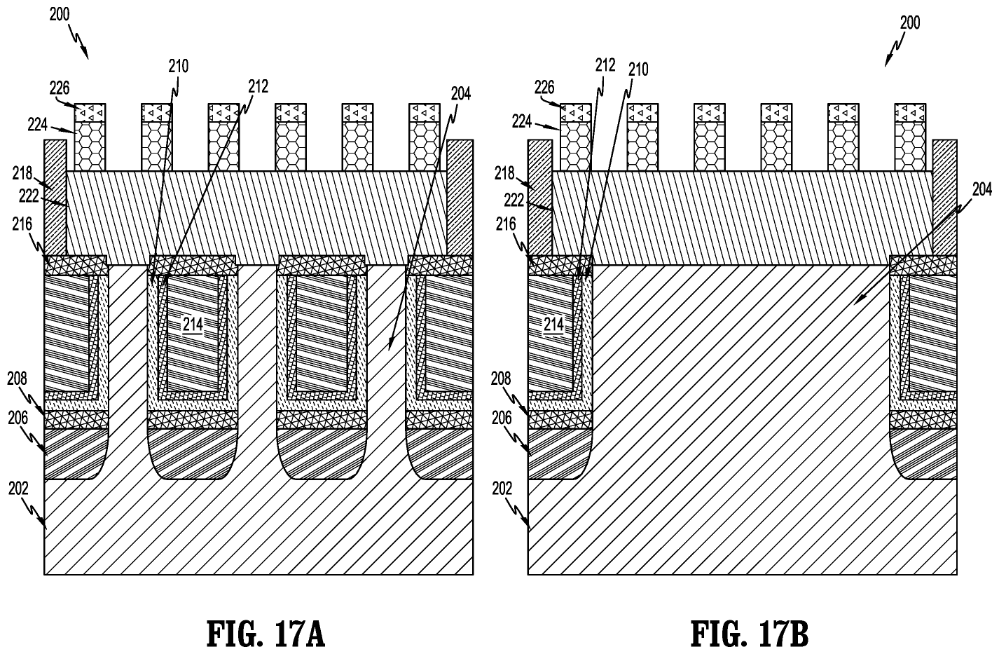

FIGS. 17A and 17B illustrate semiconductor structure 200 at an eighth-intermediate fabrication stage. During this stage, an etch is performed again using the co-polymer 230a as a mask to remove the exposed portion of OPL 224 leaving the unexposed portion of OPL 224 under hardmask 226 and the co-polymer 230a and exposing a top surface of source/drain region 222 between the resulting pillars of OPL 224, hardmask 226 and co-polymer 230a. A suitable etch to remove the exposed portion of OPL 224 includes a selective etch such as an RIE etch or a dry etch. The co-polymer 230a is selectively removed using any suitable wet etch, such as ammonia followed by a HF based solution, or a highly selective dry etch.

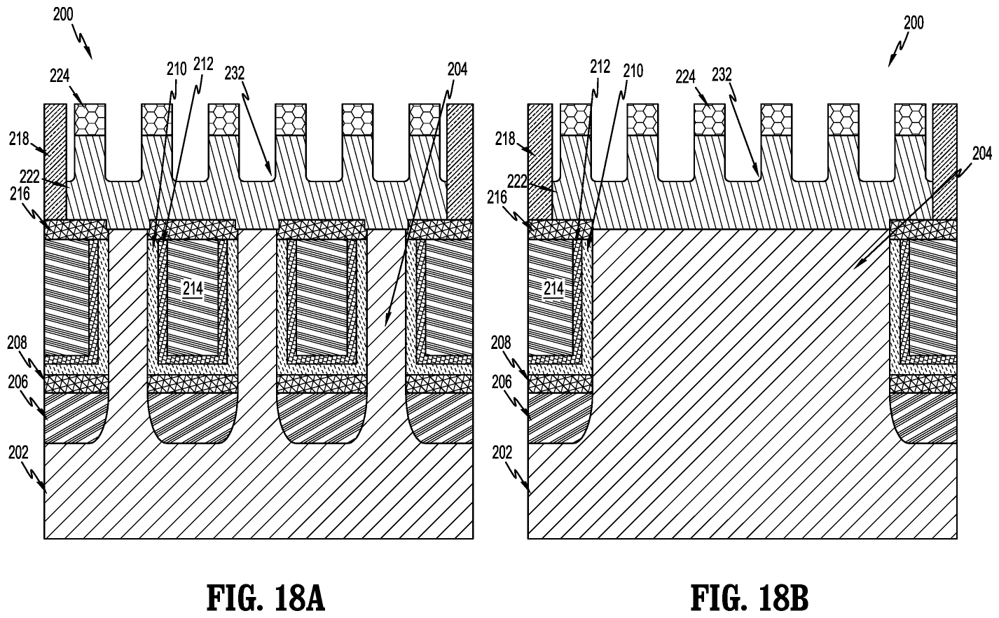

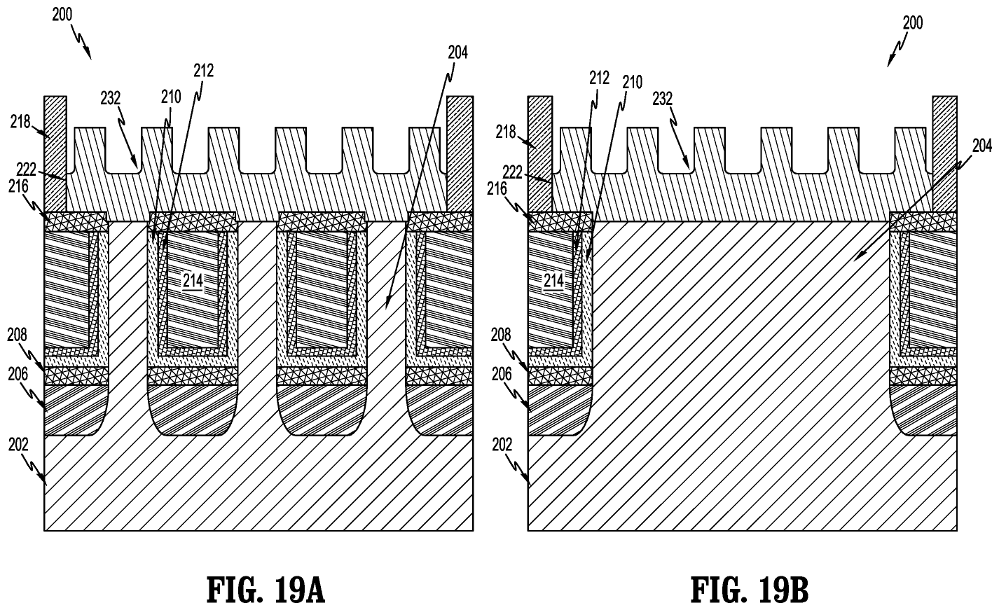

FIGS. 18A and 18B illustrate semiconductor structure 200 at a ninth-intermediate fabrication stage. During this stage, an etch is performed to recess the exposed surface of source/drain region 222 using any suitable dry etching technique. For example, the exposed surface of source/drain region 222 can be recessed by an isotropic etching process such as vapor phase dry etch. As shown in FIG. 18B, the exposed portion of source/drain region 222 between the resulting pillars of OPL 224 and hardmask 226 is etched so that the resulting top surface of source/drain region 222 will include a planar portion and at least one recessed portion 232 (see, also, FIG. 19B). Each of the recessed portions 232 can have a convex surface and a concave surface.

FIGS. 19A and 19B illustrate semiconductor structure 200 at a tenth-intermediate fabrication stage. During this stage, OPL 224 is removed by any suitable process, e.g., using a standard O₂ or N₂/H₂ based OPL ash thereby resulting in the top surface of source/drain region 222 having the planar portion and the at least one recessed portion 232. Each of the recessed portions 232 can have a convex surface and a concave surface. The at least one recessed portion 232 of the source/drain region advantageously provides for a larger contact area of semiconductor structure 200 after depositing a metal contact as discussed below thereby reducing contact resistance as compared to a source/drain region having only a planar top surface.

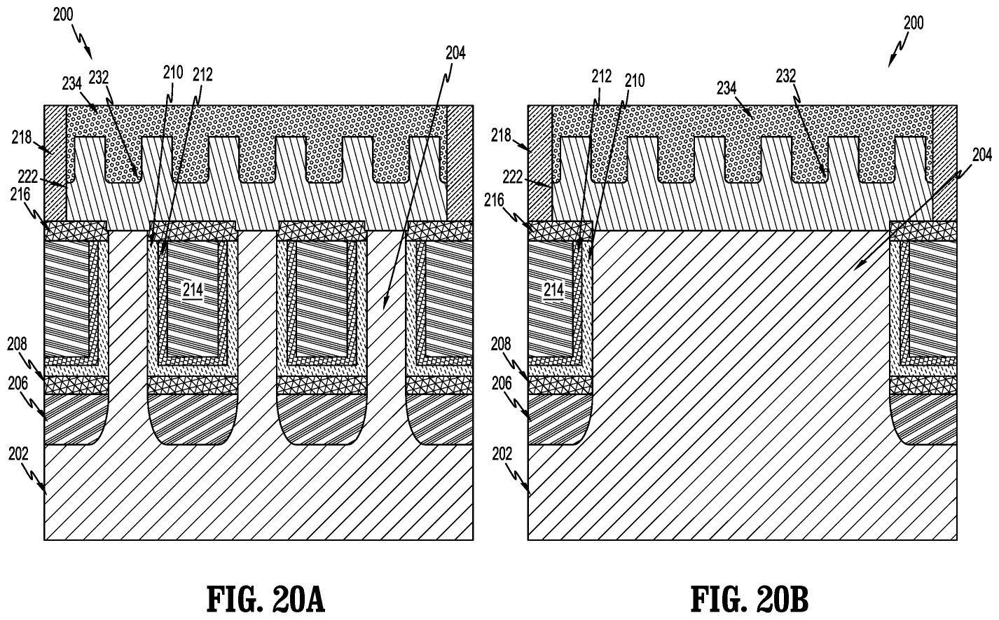

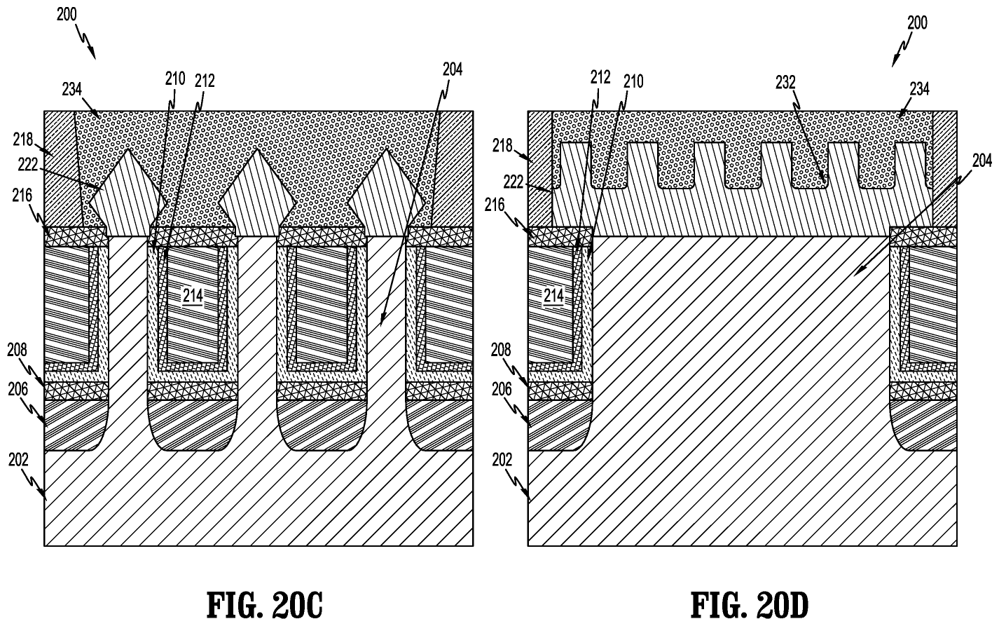

FIGS. 20A and 20B illustrate semiconductor structure 200 at an eleventh-intermediate fabrication stage. During this stage, a metal contact 234 is deposited on the top surface of source/drain region 222 including in the at least one recessed portion 232 and over the planar portion. Metal contact 234 can be deposited in a similar manner and be of a similar metal as discussed above for metal contact 132. The metal contact 234 can be planarized using, for example, a planarizing process such as CMP. Other planarization processes can include grinding and polishing.

FIGS. 20C and 20D illustrate semiconductor structure 200 at the eleventh-intermediate fabrication stage according to the alternative embodiment shown in FIG. 13C. During this stage, metal contact 234 is deposited on source/drain region 222 as discussed above. The metal contact 234 can be planarized using, for example, a planarizing process such as CMP. Other planarization processes can include grinding and polishing.

It is to be understood that the methods discussed herein for fabricating semiconductor structures can be incorporated within semiconductor processing flows for fabricating other types of semiconductor structures and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with non-limiting illustrative embodiments can be employed in applications, hardware, and/or electronic systems. Suitable hardware and systems for implementing the non-limiting illustrative embodiments may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the non-limiting illustrative embodiments provided herein, one of ordinary skill in the art will be able to contemplate other implementations and applications of the techniques described herein.

Although illustrative embodiments have been described herein with reference to the accompanying drawings, it is to be understood that the illustrated embodiments described herein are not limited to those precise embodiments, and that various other changes and modifications may be made by one skilled in art without departing from the scope or spirit of this disclosure.

What is claimed is:

1. A semiconductor structure, comprising:
a source/drain region having a top surface comprising a planar portion and at least one recessed portion; and
a metal contact disposed on the source/drain region.

2. The semiconductor structure according to claim 1, wherein the at least one recessed portion of the source/drain region comprises a convex surface and a concave surface.

3. The semiconductor structure according to claim 1, wherein the source/drain region further comprises additional recessed portions such that the top surface of the source/drain region comprises a periodic convex and concave shaped structure.

4. The semiconductor structure according to claim 1, further comprising:
a substrate comprising a semiconductor material, wherein the source/drain region is disposed on the substrate.

5. The semiconductor structure according to claim 4, further comprising:
a first channel region disposed on the substrate, the first channel region comprising a first set of nanosheet layers; and
a second channel region disposed on the substrate, the second channel region comprising a second set of nanosheet layers.

6. The semiconductor structure according to claim 5, wherein the first set of nanosheet layers and the second set of nanosheet layers each comprises silicon.

7. The semiconductor structure according to claim 5, wherein the first channel region is one of a p-type field-effect transistor region or an n-type field-effect transistor region, and the second channel region is one of an n-type field-effect transistor region or a p-type field-effect transistor region.

8. The semiconductor structure according to claim 5, wherein each of the first channel region and the second channel region further comprises a gate structure.

9. The semiconductor structure according to claim 1, further comprising:
a substrate comprising a semiconductor material;
a set of fins formed from the semiconductor material and extending vertically with respect to the substrate;
gate structures disposed on the substrate and on a portion of sidewalls of the set of fins;
spacers disposed on the gate structures and on a remaining portion of the sidewalls of the set of fins; and
the source/drain region disposed over at least a top portion of each of the set of fins.

10. The semiconductor structure according to claim 1, wherein a portion of the source/drain region disposed over a top portion of each of the set of fins comprises a diamond shaped configuration.

11. An integrated circuit, comprising:
a plurality of semiconductor structures, wherein at least one of the plurality of semiconductor structures comprises:
a source/drain region having a top surface comprising a planar portion and at least one recessed portion; and
a metal contact disposed on the source/drain region.

12. The integrated circuit according to claim 11, wherein the at least one recessed portion of the source/drain region comprises a convex surface and a concave surface.

13. The integrated circuit according to claim 11, wherein the source/drain region comprises additional recessed portions such that the top surface of the source/drain region comprises a periodic convex and concave shaped structure.

14. The integrated circuit according to claim 11, further comprising:
a substrate comprising a semiconductor material, wherein the source/drain region is disposed on the substrate.

15. The integrated circuit according to claim 14, further comprising:
a first channel region disposed on the substrate, the first channel region comprising a first set of nanosheet layers; and
a second channel region disposed on the substrate, the second channel region comprising a second set of nanosheet layers.

16. The integrated circuit according to claim 15, wherein the first channel region is one of a p-type field-effect transistor region or an n-type field-effect transistor region, and the second channel region is one of an n-type field-effect transistor region or a p-type field-effect transistor region.

17. The integrated circuit according to claim 11, further comprising:
a substrate comprising a semiconductor material;
a set of fins formed from the semiconductor material and extending vertically with respect to the substrate;
gate structures disposed on the substrate and on a portion of sidewalls of the set of fins;
spacers disposed on the gate structures and on a remaining portion of the sidewalls of the set of fins; and
the source/drain region disposed over a top portion of each of the set of fins.

18. The integrated circuit according to claim 11, wherein a portion of the source/drain region disposed over a top portion of each of the set of fins comprises a diamond shaped configuration.

19. A method for fabricating a semiconductor substrate, comprising:
forming a source/drain region having a top surface comprising a planar portion and at least one recessed portion; and
forming a metal contact on the source/drain region.

20. The method according to claim 19, wherein forming a source/drain region having a top surface comprising a planar portion and at least one recessed portion comprises a directed self-assembly patterning process.
